(19) United States
(12) Patent Application Publication
(10) Pub. No.: US 2007/0164365 A1
(43) Pub. Date: Jul. 19, 2007

(54) SINGLE STRESS LINER FOR MIGRATION STABILITY AND SPEED

(76) Inventors: Joseph Y. Chan, Fishkill, NY (US); Robert C. Wong, Poughkeepsie, NY (US)

Correspondence Address: HOFFMAN, WARNICK & D'ALESSANDRO LLC, 75 STATE ST, 14TH FL, ALBANY, NY, 12207, US

(21) Appl. No.: 11/306,943

(22) Filed: Jan. 17, 2006

(51) Int. Cl. H01L 29/94

(52) U.S. Cl. 257/369; 257/903; 257/E27.098

(57) ABSTRACT

A single stress liner is applied over different type semiconductor devices. The single stress liner avoids the problems of a dual/hybrid stress liner scheme by eliminating the meeting area. The single stress liner may be tensile or compressive. In one embodiment, the semiconductor device includes a static random access memory (SRAM) cell having numerous NFETs and PFETs. In this case, a compressive liner is placed over the SRAM cell, which is normally not ideal for the NFETs therein, but is desirable for the SRAM cell because continued miniaturization of the SRAMs typically requires slowing of the NFETs for the SRAM to maintain stabile. Where SRAM cells require increased speed, a single tensile stress liner can be implemented.

### BACKGROUND OF THE INVENTION

1. Technical Field

The invention relates generally to semiconductor devices, and more particularly, to application of a single stress liner to provide stable migration and/or speed.

2. Background Art

The application of stresses to certain semiconductor devices such as field effect transistors (FETs) is known to improve their performance. When applied in a longitudinal direction (i.e., in the direction of current flow), tensile stress is known to enhance electron mobility (or n-channel FET (NFET) drive currents) while compressive stress is known to enhance hole mobility (or p-channel FET (PFET) drive currents). One way to apply such stresses to a FET is the use of intrinsically-stressed barrier silicon nitride liners. For example, a tensile-stressed silicon nitride liner may be used to cause tension in an NFET channel while a compressively-stressed silicon nitride liner may be used to cause compression in a PFET channel. Accordingly, a dual/hybrid liner scheme is typically used to induce the desired stresses in adjacent NFETs and PFETs.

One challenge for forming a dual/hybrid liner scheme is that it requires a clear meeting area between the two liners, which is very difficult to generate in a scaled down layout. Another challenge relative to dual/hybrid liners is accommodating contacts near the liner boundary. In particular, spacing between NFETs and PFETs in many devices is too small to accommodate contacts near the meeting area because of the bumpy contour. Contacts may be necessary, for example, to connect to polysilicon conductor layers. In some instances, there is simply no way to make reliable contacts. In other situations, the structure can be adjusted to accommodate the contacts further away from the liner boundary. In these latter cases, however, the structure still results in devices with ambiguous strains. The PFETs may get partial tensile stain or the NFETs may get partial compressive strain around the liner boundary.

With special regard to static random access memory (SRAM) cells, another challenge for use of a dual/hybrid stress liner is maintaining stability. In particular, the continued miniaturization of certain SRAMs has resulted in instability, which necessitates slowing the NFETs therein using high threshold voltage (HVT) implants.

In view of the foregoing, there is a need in the art to apply stress to certain semiconductor devices without facing the problems described above.

### SUMMARY OF THE INVENTION

A single stress liner is applied over different type semiconductor devices. The single stress liner avoids the problems of a dual/hybrid stress liner scheme by eliminating the meeting area. The single stress liner may be tensile or compressive. In one embodiment, the semiconductor device includes a static random access memory (SRAM) cell having numerous NFETs and PFETs. In this case, in one embodiment, a compressive liner is placed over the SRAM cell, which is normally not ideal for the NFETs therein, but is desirable for the SRAM cell because continued miniaturization of the SRAMs typically requires slowing of the NFETs for the SRAM to maintain stability. Where SRAM cells require increased speed, a single tensile stress liner can be implemented while the stability is maintained by other means.

A first aspect of the invention provides a static random access memory (SRAM) cell comprising: a plurality of n-type field effect transistors (NFETs); a plurality of p-type field effect transistors (PFETs); and a single stress liner applied over the plurality of NFETs and the plurality of PFETs.

A second aspect of the invention provides a method of stabilizing a static random access memory (SRAM) cell including a plurality of n-type field effect transistors (NFETs) and a plurality of p-type FETs (PFETs), the method comprising the steps of: providing the SRAM cell; and forming a single compressive stress liner over the plurality of NFETs and the plurality of PFETs.

A third aspect of the invention provides a method of increasing speed of a static random access memory (SRAM) cell including a plurality of n-type field effect transistors (NFETs) and a plurality of p-type FETs (PFETs), the method comprising the steps of: providing the SRAM cell; and forming a single tensile stress liner over the plurality of NFETs and the plurality of PFETs.

A fourth aspect of the invention provides a semiconductor device comprising: a plurality of n-type field effect transistors (NFETs); a plurality of p-type field effect transistors (PFETs); and a single stress liner applied over the plurality of NFETs and the plurality of PFETs.

The illustrative aspects of the present invention are designed to solve the problems herein described and other problems not discussed, which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a plan view of one embodiment of a semiconductor device according to the invention.

FIG. 2 shows a simplified side view of one embodiment of the semiconductor device of FIG. 1.

FIGS. 3-5 show plan views of conventional alternative semiconductor devices that benefit from the teachings of the invention.

FIG. 6 shows a data table illustrating some of the benefits of the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

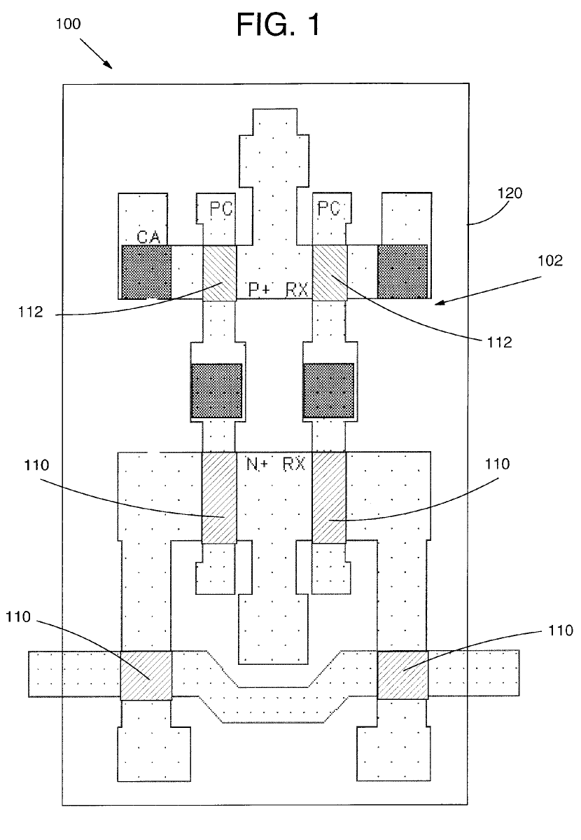

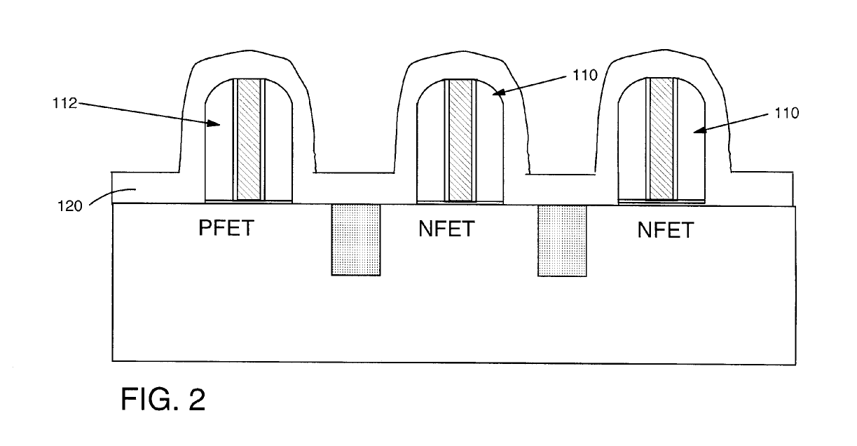

Referring to FIGS. 1 and 2, a semiconductor device 100 according to one embodiment of the invention is illustrated. It should be understood that the drawings are not to scale, and that FIG. 2 has been simplified compared to FIG. 1 for clarity purposes. In one embodiment, semiconductor device 100 includes a static random access memory (SRAM) cell 102. It should be recognized, however, that the teachings of the invention are applicable to a variety of other semiconductor devices, which are considered within the scope of the invention. Semiconductor device 100 includes a plurality of n-type field effect transistors (NFETs) 110 and a plurality of p-type field effect transistors (PFETs) 112. In the case of an SRAM cell 102, the device may include a high density of the NFETs 110 and the PFETs 112, for example, in a six transistor structure having at least two PFETs 112 and at least four NFETs 110. “High density” refers to special layouts with dimensions approximately 50% below general technology ground rules. In contrast to conventional devices, however, semiconductor device 100 includes a single stress liner 120 applied over the plurality of NFETs 110 and the plurality of PFETs 112.

Single stress liner 120 may vary in form. In one embodiment, single stress liner 120 includes a compressive material, e.g., compressive silicon nitride (Si₃N₄). In this case, single stress liner 120 slows operation of NFETs 110, thus making SRAM cell 102 more stable. In another embodiment, single stress liner 120 includes a tensile material, e.g., tensile silicon nitride (Si₃N₄). In this case, single stress liner 120 increases a speed of SRAM cell 102.

The invention also includes one embodiment of a method for stabilizing a SRAM cell 102 including NFETs 110 and PFETs 112. In this embodiment, the method includes providing SRAM cell 102, i.e., using any now known or later developed processing, and forming a single compressive stress liner 120 over NFETs 110 and PFETs 112. As mentioned above, the providing step may include providing a high density of the NFETs and the PFETs. The invention also includes one embodiment of a method of increasing a speed of SRAM cell 102 including NFETs 110 and PFETs 112. In this embodiment, the method includes providing SRAM cell 102, as described above, and forming a single tensile stress liner 120 over NFETs 110 and PFETs 112.

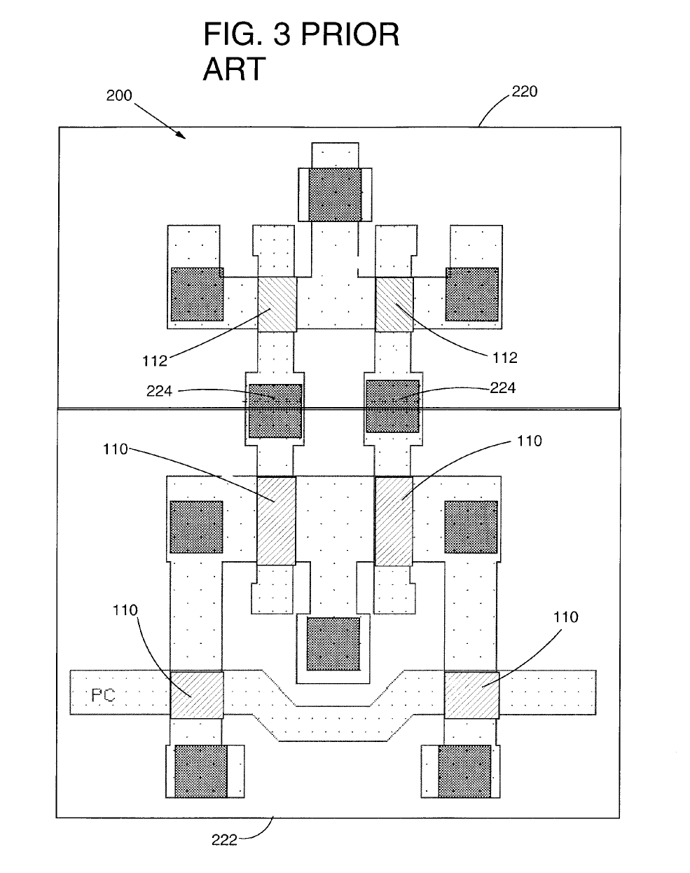

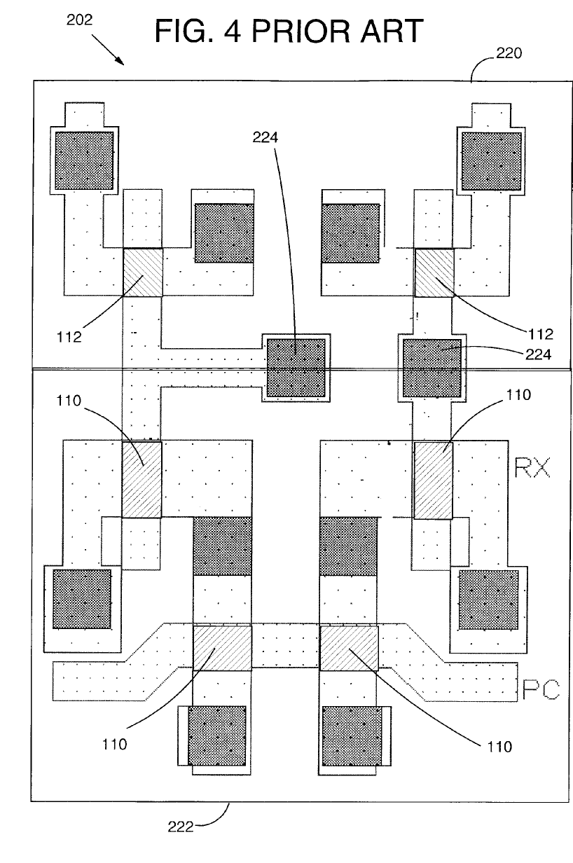

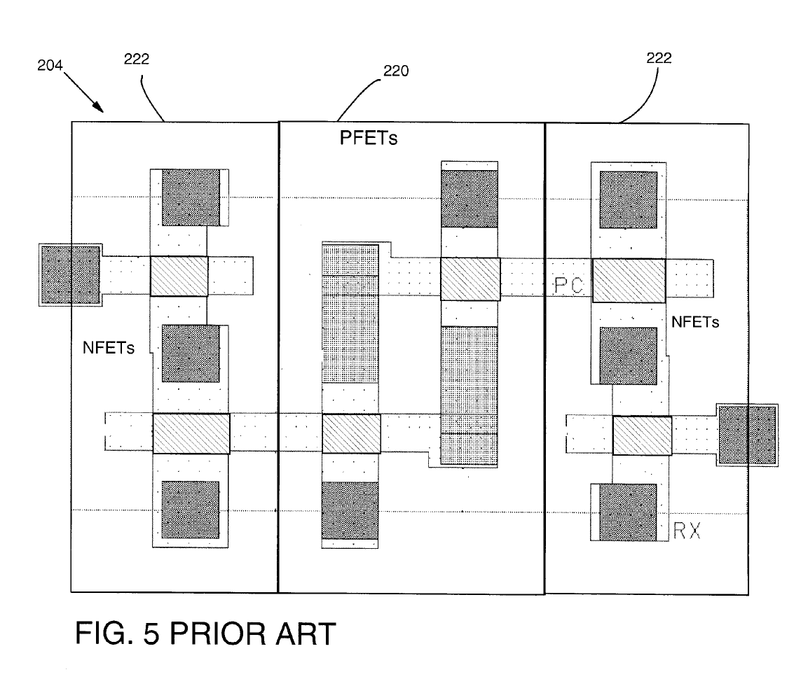

FIGS. 3-5 show plan views of conventional alternative semiconductor devices that would be aided by the teachings of the invention. FIG. 3 shows a device 200 including congestion of a dual liner boundary and contacts 224 right at the liner meeting area for a conventional design with a compressive liner 220 and a tensile liner 222. The edge of compressive liner 220 may be overhanging over the edge of tensile liner 222. The rugged contour will not allow a reliable metal contact 224. FIG. 4 shows similar difficulties in an alternative conventional design 202. FIG. 5 shows another alternative conventional design 204 with no contacts near the liner boundary. In this case, the dual liner problem is less severe. However, the boundary is still too close to the NFETs and the PFETs and the desired strains cannot be guaranteed. Each of the above-described semiconductor devices would be aided by the single stress liner according to the invention.

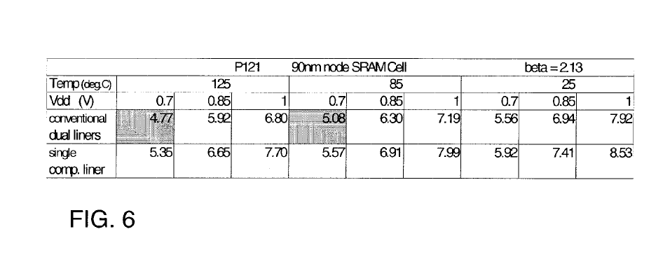

Some other benefits of a single compressive liner are illustrated in the table of FIG. 6. The numbers in the table represent Access Disturb Margins (ADM) in units of sigma at various temperature and Vdd. SRAM cells with an ADM below a 5.2 sigma are considered unstable. At 5.2 sigma, the SRAM cell failure rate is around 1 disturb in 5 million cells. The conventional layout with dual liners cannot support low Vdd operation at 0.7V, where the ADM is below 5.2 sigma at 125° C. and 85° C. The single compressive liner design will increase the cell stability above 5.2 sigma. An additional benefit of a single tensile liner is the faster access at a cost of some stability degradation.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A static random access memory (SRAM) cell comprising:
a plurality of n-type field effect transistors (NFETs);
a plurality of p-type field effect transistors (PFETs); and
a single stress liner applied over the plurality of NFETs and the plurality of PFETs.

2. The SRAM cell of claim 1, wherein the single stress liner includes a compressive material.

3. The SRAM cell of claim 2, wherein the single stress liner slows operation of the plurality of NFETs.

4. The SRAM cell of claim 2, wherein the SRAM cell has a high density of the NFETs and the PFETs.

5. The SRAM cell of claim 1, wherein the single stress liner includes a tensile material.

6. The SRAM cell of claim 5, wherein the single stress liner increases a speed of the SRAM cell.

7. The SRAM cell of claim 1, wherein the plurality of PFETs includes at least two PFETs, and the plurality of NFETs includes at least four NFETs.

8. A method of stabilizing a static random access memory (SRAM) cell including a plurality of n-type field effect transistors (NFETs) and a plurality of p-type FETs (PFETs), the method comprising the steps of:
providing the SRAM cell; and
forming a single compressive stress liner over the plurality of NFETs and the plurality of PFETs.

9. The method of claim 8, wherein the SRAM cell providing step includes providing a high density of the NFETs and the PFETs.

10. A method of increasing speed of a static random access memory (SRAM) cell including a plurality of n-type field effect transistors (NFETs) and a plurality of p-type FETs (PFETs), the method comprising the steps of:
providing the SRAM cell; and
forming a single tensile stress liner over the plurality of NFETs and the plurality of PFETs.

11. A semiconductor device comprising:
a plurality of n-type field effect transistors (NFETs);
a plurality of p-type field effect transistors (PFETs); and
a single stress liner applied over the plurality of NFETs and the plurality of PFETs.

12. The semiconductor device of claim 11, wherein the single stress liner includes a compressive material.

13. The semiconductor device of claim 12, wherein the semiconductor device includes a static random access memory (SRAM) cell, and the single stress liner slows operation of the plurality of NFETs.

14. The semiconductor device of claim 11, wherein the single stress liner includes a tensile material.

15. The semiconductor device of claim 14, wherein the semiconductor device includes a static random access memory (SRAM) cell, and the single stress liner increases a speed of the SRAM cell.

16. The semiconductor device of claim 11, wherein the plurality of PFETs includes at least two PFETs, and the plurality of NFETs includes at least four NFETs.
